(19) United States
(12) Patent Application Publication
(10) Pub. No.: US 2025/0155379 A1
(43) Pub. Date: May 15, 2025

(54) PROCESS MONITORING METHOD AND DEVICE

(71) Applicant: UNIVERSITY-INDUSTRY FOUNDATION(UIF), YONSEI UNIVERSITY, Seoul (KR)

(72) Inventors: Mann Ho CHO, Seoul (KR); Jong Hoon KIM, Gimpo-si, Gyeonggi-do (KR); Kwang Sik JEONG, Seoul (KR)

(73) Assignee: UNIVERSITY-INDUSTRY FOUNDATION(UIF), YONSEI UNIVERSITY, Seoul (KR)

(21) Appl. No.: 18/833,916

(22) PCT Filed: Jan. 19, 2023
(86) PCT No.: PCT/KR2023/000933

§ 371 Date: Jul. 29, 2024

(30) Foreign Application Priority Data
Jan. 28, 2022 (KR) 10-2022-0013499

(51) Int. Cl. G01N 21/95; G01N 21/3563; G01N 21/3581

(52) U.S. Cl. CPC G01N 21/9501; G01N 21/3563; G01N 21/3581

(57) ABSTRACT

Provided is a process monitoring method including injecting a laser beam capable of forming excited carriers in a thin film, irradiating an electromagnetic wave onto the thin film while the excited carriers in the thin film are recombining, measuring characteristic information of the electromagnetic wave reacting with the excited carriers in the thin film, and determining whether the thin film is normal, by comparing reference data to a result using the measured characteristic information of the electromagnetic wave.

### TECHNICAL FIELD

The present invention relates to a process monitoring method and process monitoring apparatus, and more particularly, to a process monitoring method and process monitoring apparatus capable of analyzing defects of a thin film in a non-contact and non-destructive manner.

### BACKGROUND ART

Semiconductor technology is evolving from patterns with a size of hundreds of nanometers to ultra-fine patterns with a size of several to tens of nanometers. As such, formation of a thin film in good quality is critical in semiconductor devices. Therefore, a process monitoring method and process monitoring apparatus capable of monitoring defects of a thin film in a non-contact and non-destructive manner in a semiconductor manufacturing process needs to be developed. A related document includes Korean Patent Publication No. 10-2004-0106107.

### DETAILED DESCRIPTION OF THE INVENTION

### Technical Problem

The present invention provides a process monitoring method and process monitoring apparatus for measuring a defect density by type of thin film defects of a semiconductor device in a non-contact and non-destructive manner.

However, the above description is an example, and the scope of the present invention is not limited thereto.

### Technical Solution

According to an aspect of the present invention, there is provided a process monitoring method including injecting a laser beam capable of forming excited carriers in a thin film, irradiating an electromagnetic wave onto the thin film while the excited carriers in the thin film are recombining, measuring characteristic information of the electromagnetic wave reacting with the excited carriers in the thin film, and determining whether the thin film is normal, by comparing reference data to a result using the measured characteristic information of the electromagnetic wave.

The characteristic information of the electromagnetic wave may include a transmittance or reflectance of the electromagnetic wave.

The result using the measured characteristic information of the electromagnetic wave may include a carrier recombination time constant calculated through inverse Laplace transform on a transmittance decay function of the electromagnetic wave over time.

The carrier recombination time constant may be dividable by type of defects in the thin film and be inversely proportional to a defect density in the thin film.

The carrier recombination time constant may be dividable into a first carrier recombination time constant based on a first type of defects in the thin film and a second carrier recombination time constant based on a second type of defects in the thin film.

The first carrier recombination time constant may be inversely proportional to a first defect density based on the first type of defects, the second carrier recombination time constant may be inversely proportional to a second defect density based on the second type of defects, and a size relationship between the first and second carrier recombination time constants may be opposite to a size relationship between the first and second defect densities in the thin film.

The process monitoring method may further include, when a defect type indicating that the thin film is abnormal is derived by comparing the reference data to the carrier recombination time constant divided by type of defects in the thin film, controlling process conditions related to the derived defect type.

The transmittance decay function of the electromagnetic wave over time may be simulatable by Equation 1.

$$\frac{Δ T}{{T}_{0}} ( t ) = {\sum }_{i = 1}^{n} {a}_{i} {e}^{- t / {τ}_{i}} \qquad ( Equation 1 )$$

(ΔT a transmittance decay change of an electromagnetic wave transmitting through a thin film, T₀ a transmittance of the electromagnetic wave when a laser beam for forming excited carriers is not injected into the thin film, n a number of defect types in the thin film, aᵢ a carrier recombination contribution based on each type of defects in the thin film, t time, and τᵢ a carrier recombination time constant based on each type of defects) The laser beam may include a femtosecond laser beam.

The electromagnetic wave may include a terahertz wave.

The excited carriers in the thin film may include excited free electrons or holes in the thin film.

According to another aspect of the present invention, there is provided a process monitoring apparatus including a beam emitter for generating a laser beam to be injected into a thin film to form excited carriers in the thin film, an electromagnetic wave irradiator for irradiating an electromagnetic wave onto the thin film while the excited carriers in the thin film are recombining, a measurer for measuring characteristic information of the electromagnetic wave reacting with the excited carriers in the thin film, and an operation controller for determining whether the thin film is normal, by comparing reference data to a result using the measured characteristic information of the electromagnetic wave.

The measurer may measure a transmittance or reflectance of the electromagnetic wave as the characteristic information of the electromagnetic wave.

The operation controller may calculate a carrier recombination time constant through inverse Laplace transform on a transmittance decay function of the electromagnetic wave over time, as the result using the measured characteristic information of the electromagnetic wave. The carrier recombination time constant may be dividable by type of defects in the thin film and be inversely proportional to a defect density in the thin film. The carrier recombination time constant may be dividable into a first carrier recombination time constant based on a first type of defects in the thin film and a second carrier recombination time constant based on a second type of defects in the thin film. The first carrier recombination time constant may be inversely proportional to a first defect density based on the first type of defects, the second carrier recombination time constant may be inversely proportional to a second defect density based on the second type of defects, and a size relationship between the first and second carrier recombination time constants may be opposite to a size relationship between the first and second defect densities in the thin film.

When a defect type indicating that the thin film is abnormal is derived by comparing the reference data to the carrier recombination time constant divided by type of defects in the thin film, the operation controller may control process conditions related to the derived defect type.

The beam emitter may generate a femtosecond laser beam as the laser beam.

The electromagnetic wave irradiator may irradiate a terahertz wave as the electromagnetic wave.

### Advantageous Effects

According to the afore-described embodiments of the present invention, a process monitoring method and process monitoring apparatus for measuring a defect density by type of thin film defects of a semiconductor device in a non-contact and non-destructive manner may be implemented.

However, the scope of the present invention is not limited to the above effect.

### DESCRIPTION OF THE DRAWINGS

FIG. 1 is a flowchart of a process monitoring method according to an embodiment of the present invention.

FIG. 2 is a block diagram of a process monitoring apparatus for performing a process monitoring method according to an embodiment of the present invention.

FIG. 3 is a diagram for describing a procedure of measuring recombination of free electrons over time by using a process monitoring method according to an embodiment of the present invention.

FIG. 4 is a graph showing how a transmittance of an electromagnetic wave decays over time in a process monitoring method according to an embodiment of the present invention.

FIG. 5 is a graph showing a result of measuring a transmittance decay of an electromagnetic wave over time in a process monitoring method according to an embodiment of the present invention.

FIG. 6 is a graph showing a result of dividing a time constant by using inverse Laplace transform in a process monitoring method according to an embodiment of the present invention.

FIG. 7 is a graph showing time constants of samples of defects 1 divided through inverse Laplace transform in a process monitoring method according to an embodiment of the present invention.

FIG. 8 is a graph showing time constants of samples of defects 2 divided through inverse Laplace transform in a process monitoring method according to an embodiment of the present invention.

FIG. 9 is a schematic diagram showing process monitoring in a process monitoring method according to an embodiment of the present invention.

FIGS. 10 and 11 are diagrams for describing a procedure of determining a pass or fail of a process through comparison with reference data in a process monitoring method according to an embodiment of the present invention.

FIG. 12 is a graph showing a concept of determining a pass or fail of a process by comparing time constants using mathematical processing in view of first defects in a process monitoring method according to an embodiment of the present invention.

FIG. 13 is a graph showing a concept of determining a pass or fail of a process by comparing time constants using mathematical processing in view of second defects in a process monitoring method according to an embodiment of the present invention.

### MODE OF THE INVENTION

Hereinafter, the present invention will be described in detail by explaining embodiments of the invention with reference to the attached drawings.

The invention may, however, be embodied in many different forms and should not be construed as being limited to the embodiments set forth herein; rather, these embodiments are provided so that this disclosure will be thorough and complete, and will fully convey the concept of the invention to one of ordinary skill in the art. In the drawings, the thicknesses or sizes of layers are exaggerated for clarity and convenience of explanation.

Embodiments of the invention are described herein with reference to schematic illustrations of idealized embodiments (and intermediate structures) of the invention. As such, variations from the shapes of the illustrations as a result, for example, of manufacturing techniques and/or tolerances, are to be expected. Thus, the embodiments of the invention should not be construed as limited to the particular shapes of regions illustrated herein, but are to include deviations in shapes that result, for example, from manufacturing.

The present invention relates to a method of analyzing recombination of carriers optically excited using a femtosecond laser beam through time-resolved measurement of transmission and reflection of a terahertz wave to analyze a defect density among semiconductor characteristics in a non-contact and non-destructive manner, and is characterized in that a process is monitored and controlled by separately analyzing densities and types of defects of a compound semiconductor based on a recombination rate of optically excited carriers of the compound semiconductor.

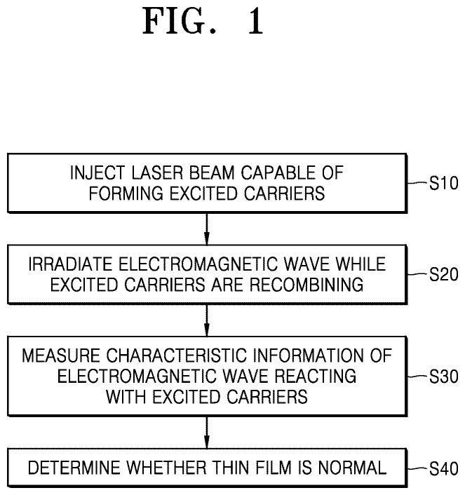

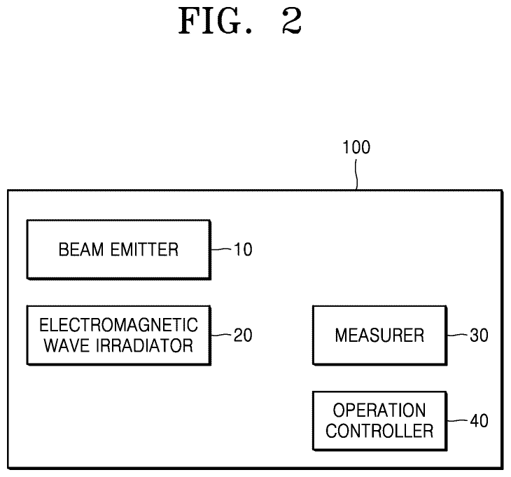

FIG. 1 is a flowchart of a process monitoring method according to an embodiment of the present invention, and FIG. 2 is a block diagram of a process monitoring apparatus for performing a process monitoring method according to an embodiment of the present invention.

Referring to FIG. 1, the process monitoring method according to an embodiment of the present invention includes injecting a laser beam capable of forming excited carriers in a thin film (S10), irradiating an electromagnetic wave onto the thin film while the excited carriers in the thin film are recombining (S20), measuring characteristic information of the electromagnetic wave reacting with the excited carriers in the thin film (S30), and determining whether the thin film is normal, by comparing reference data to a result using the measured characteristic information of the electromagnetic wave (S40).

In the process monitoring method, the laser beam may include a femtosecond laser beam, and the electromagnetic wave may include a terahertz wave.

In the process monitoring method, the characteristic information of the electromagnetic wave may include a transmittance or reflectance of the electromagnetic wave, and the result using the measured characteristic information of the electromagnetic wave may include a carrier recombination time constant calculated through inverse Laplace transform on a transmittance decay function of the electromagnetic wave over time.

Referring to FIG. 2, a process monitoring apparatus 100 for performing the process monitoring method according to an embodiment of the present invention includes a beam emitter 10 for generating a laser beam to be injected into a thin film to form excited carriers in the thin film, an electromagnetic wave irradiator 20 for irradiating an electromagnetic wave onto the thin film while the excited carriers in the thin film are recombining, a measurer 30 for measuring characteristic information of the electromagnetic wave reacting with the excited carriers in the thin film, and an operation controller 40 for determining whether the thin film is normal, by comparing reference data to a result using the measured characteristic information of the electromagnetic wave.

The process monitoring apparatus 100 may further include a display for displaying the result of comparing the reference data to the result using the measured characteristic information of the electromagnetic wave, and/or the result of determining whether the thin film is normal.

Referring to FIGS. 1 and 2 together, in the process monitoring apparatus 100 for performing the process monitoring method according to an embodiment of the present invention, the beam emitter 10 may perform at least a portion of the step S10 for injecting the laser beam capable of forming the excited carriers into the thin film, the irradiator 20 may perform at least a portion of the step S20 for irradiating the electromagnetic wave onto the thin film while the excited carriers in the thin film are recombining, the measurer 30 may perform at least a portion of the step S30 for measuring the characteristic information of the electromagnetic wave reacting with the excited carriers in the thin film, and the operation controller 40 may perform at least a portion of the step S40 for determining whether the thin film is normal, by comparing the reference data to the result using the measured characteristic information of the electromagnetic wave.

The steps of the process monitoring method according to an embodiment of the present invention will now be described in detail. Therefore, the following description and the description provided above in relation to FIGS. 1 and 2 may also be applied to the process monitoring apparatus 100 for performing the process monitoring method of the present invention.

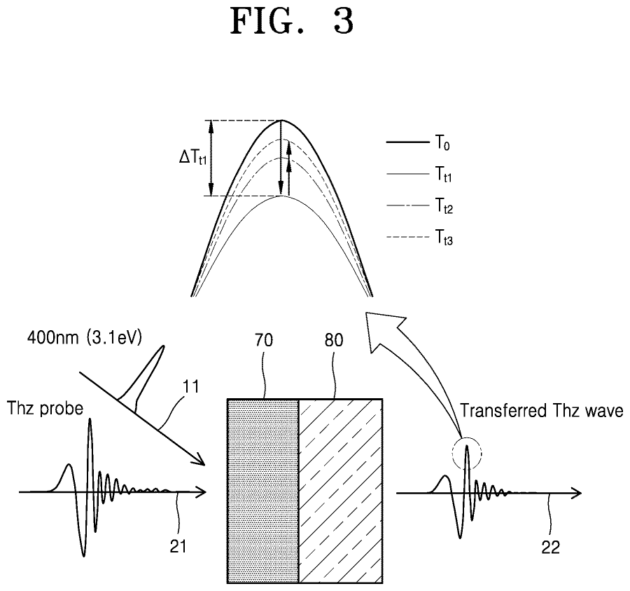

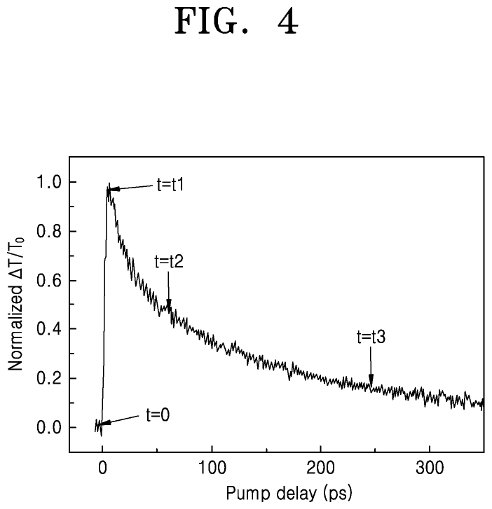

FIG. 3 is a diagram for describing a procedure of measuring recombination of free electrons over time by using a process monitoring method according to an embodiment of the present invention, and FIG. 4 is a graph showing how a transmittance of an electromagnetic wave decays over time in a process monitoring method according to an embodiment of the present invention. In FIGS. 3 and 4, ΔT refers to a transmittance decay change of an electromagnetic wave, and T₀ refers to a transmittance of the electromagnetic wave when a laser beam for forming excited carriers is not injected into a thin film. “Pump delay” refers to a time elapsed from when the laser beam is injected into the thin film, and t=t1, t=t2, and t=t3 refer to timings at which a terahertz wave is irradiated after the laser beam is injected into the thin film.

Carriers (e.g., free electrons or holes) excited by a laser beam 11 injected into a thin film 70 formed on a substrate 80 recombine with a specific time constant through various paths. The laser beam injected into the thin film may be understood as a pump beam in that it forms excited carriers in the thin film.

In general, a recombination time constant based on a recombination path includes i) a recombination time constant based on an intra-valley scattering path (<ps), ii) a recombination time constant based on an inter-valley scattering path (to several ps), iii) a recombination time constant based on a defect-assisted recombination path (several ps to several ns), and iv) a recombination time constant based on an inter-band scattering path (hundreds of ps to μs).

Because the time constant of the defect-assisted recombination procedure is inversely proportional to a defect density of a material of the thin film 70, the defect density of the thin film 70 may be measured by analyzing the time constant of the recombination procedure.

In this case, to measure recombination of free electrons, for example, a terahertz wave may be used as an electromagnetic wave 21 or 22. For convenience of understanding, FIG. 3 separately shows a terahertz wave after being irradiated from a Thz probe of a beam emitter and before being transmitted through the thin film 70 (i.e., the electromagnetic wave 21), and a transferred Thz wave after being transmitted through the thin film 70 (i.e., the electromagnetic wave 22). The terahertz wave is an electromagnetic wave with a frequency of about 0.01 THz to 10 THz and is characterized in that it selectively reacts with free electrons. Therefore, by measuring changes in intensity of the terahertz wave transmitted through the material of the semiconductor thin film 70, the characteristics and quantity of free electrons inside the thin film 70 may be measured in a non-contact manner.

After a certain time is elapsed from when, for example, a femtosecond laser beam is injected as the laser beam 11 capable of forming excited carriers in the thin film, when a terahertz wave is transmitted as the electromagnetic wave 21 reacting with the excited carriers, a transmittance of the terahertz wave, i.e., the electromagnetic wave 22, is reduced by free electrons excited in the thin film 70 by the femtosecond laser beam. Therefore, the quantity of free electrons generated and recombined may be found out in a non-contact and non-destructive manner.

In this case, a recombination time constant of free electrons may be measured by measuring changes in transmittance of the terahertz wave over time after the femtosecond laser beam is injected, and thus a defect density of the thin film 70 constituting a semiconductor device may be measured in a non-contact and non-destructive manner.

When the excited free electrons recombine through multiple paths, the recombination time constant may be divided into time constants of free electrons recombining through different paths. Using this, when multiple types of defects contribute to defect-assisted recombination, densities of different types of defects may be independently measured by dividing the recombination time constant. That is, the carrier recombination time constant may be divided by type of defects in the thin film and be inversely proportional to a defect density in the thin film.

For example, through time-resolved measurement on recombination of optically excited free electrons in a GaSb thin film with both structural defects (or first defects) and atomic defects (or second defects), time constants of recombination procedures by the first and second defects may be independently measured and densities of the two types of defects may be independently obtained to analyze the correlation with the characteristics of the compound semiconductor.

As a result of controlling Sb flux while the GaSb thin film is growing in a molecular beam epitaxial (MBE) manner, thin films controlled in roughness, which is known to be influenced by structural defects (e.g., line defects and lattice defects), and carrier density, which is known to be influenced by defects caused by deletion or addition of atoms in a compound semiconductor, were formed. Three samples controlled in roughness within a difference of about 0.15 nm, carrier concentration within a difference of about 1E17/cm⁻³, and mobility within a difference of about 30 cm²/VS were produced by controlling the flux of Sb during the growth (see Table 1). These subtle differences may be distinguished only through a method that requires direct contact, e.g., atomic force microscopy (AFM) or electrical measurement, and may not be easily analyzed through an optical method.

TABLE 1

| Sample | A | B | C |
|---|---|---|---|
| Sb Flux (mol/cm²) | 1.10E−06 | 4.74E−07 | 7.20E−07 |
| Carrier Concentration (cm⁻³) | 2.37E+17 | 1.89E+17 | 2.50E+17 |
| Mobility (cm²/V-s) | 320.9 | 354.9 | 343.5 |
| Specific Resistance (ohm-cm) | 0.08195 | 0.09307 | 0.07782 |
| Sheet Carrier Density | 1.19E+12 | 9.45E+11 | 1.17E+12 |
| RMS Roughness (nm) | 0.814 | 0.714 | 0.702 |

Electrons excited by the laser beam recombine between hundreds of ps to change the transmittance of the terahertz wave over time and a decay of the transmittance over time in this case satisfies Equation 1 on the assumption that n types of defects are present.

$$\frac{Δ T}{{T}_{0}} ( t ) = {\sum }_{i = 1}^{n} {a}_{i} {e}^{- t / {τ}_{i}} \qquad [ Equation 1 ]$$

(ΔT: a transmittance decay change of an electromagnetic wave, T₀: a transmittance of the electromagnetic wave when a laser beam for forming excited carriers is not injected into a thin film, n: the number of defect types in the thin film, aᵢ: a carrier recombination contribution based on each type of defects in the thin film, t: time, and τᵢ: a carrier recombination time constant based on each type of defects)

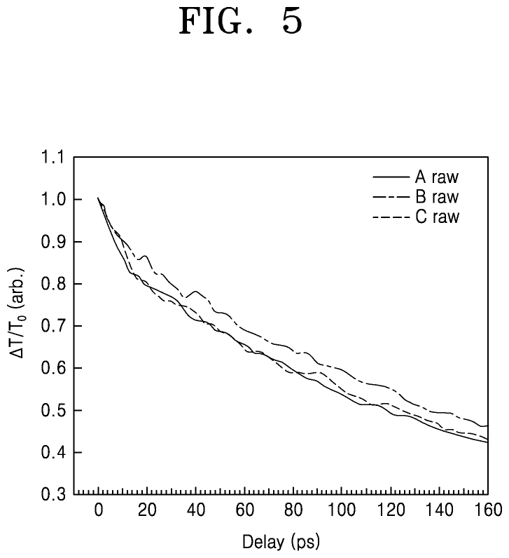

FIG. 5 is a graph showing a result of measuring a transmittance decay of an electromagnetic wave over time in a process monitoring method according to an embodiment of the present invention. That is, a transmittance of a terahertz wave over time after optical pumping is applied to each sample is shown. In FIG. 5, “Delay” refers to a time elapsed from when a laser beam is injected into a thin film.

Referring to FIG. 5, samples A, B, and C exhibit different transmittance decays based on defect densities. For example, at an early stage, samples A and C exhibit faster decays compared to sample B. At a late stage, samples A, B, and C exhibit similar decay gradients. Assuming that first defects causing a fast decay and second defects causing a slow decay are present, sample B is expected to have relatively fewer first defects and has the lowest carrier concentration and the highest mobility. At the late stage, sample A exhibits a slightly faster decay compared to samples B and C. The roughness of sample A is the highest. However, due to a subtle difference in defect density between the thin films, the difference between the samples may not be easily clearly identified only based on the decay tendencies.

Mathematical processing may be adopted to distinguish time constants between similar decay signals. In the present invention, it is found that a time-based decay function may be transformed into a time-constant-based function by using inverse Laplace transform and that the time-based decays shown in FIG. 5 may be transformed into time constant distributions.

A transmittance change curve of a terahertz wave over time occurs due to a plurality of decay factors. Because measurement data is brought when the influences of all decay factors are added together, a decay curve S(t) is expressed as the integral of a probability density F(k) multiplied by the decay function for all values of k (see Equation 2).

$$S ( t ) = {\int }_{0}^{∞} F ( k ) exp ( - kt ) dk \qquad [ Equation 2 ]$$

This is the same as the Laplace transform formula in form and inverse Laplace transform is required to calculate F(k) indicating the influence of the decay factors. Because F(k) may not be accurately calculated, a procedure of reducing an error rate by applying an approximation function is required and transform is performed by setting a margin of error rate based on a desired accuracy. As a result, an approximation of a time constant k and an approximation of the approximation function F(k) may be obtained, and F(k) may be considered as the influence of the decay factors.

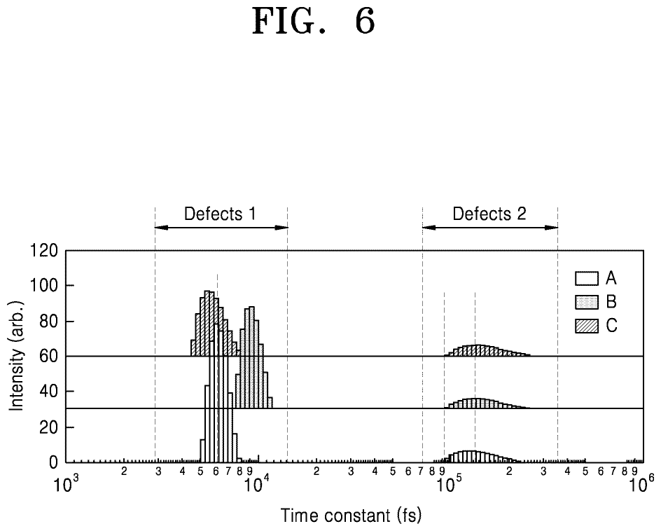

FIG. 6 is a graph showing a result of dividing a time constant by using inverse Laplace transform in a process monitoring method according to an embodiment of the present invention. That is, FIG. 6 shows a result of transforming a transmittance of a terahertz wave over time into a time-constant-based function by using inverse Laplace transform.

Referring to FIG. 6, as a result of transforming the raw data of FIG. 5 into a time-constant-based function through inverse Laplace transform, it is shown that the measurement results shown in FIG. 5 may be divided into time constants of two regions. For example, a carrier recombination time constant may be divided into a first carrier recombination time constant based on a first type of defects in a thin film and a second carrier recombination time constant based on a second type of defects in the thin film. When the first and second types of defects are defined as first defects (or defects 1) and second defects (or defects 2), a recombination time constant by the first defects satisfies C<A<B and a recombination time constant by the second defects satisfies A<B=C.

Compared to the characteristics of a compound semiconductor obtained by the present inventor based on another experiment, it may be understood that the second defects are related to the roughness of the thin film and the first defects are related to the carrier concentration in the thin film, and thus it may be concluded that the second defects are related to structural defects and the first defects are related to atomic defects.

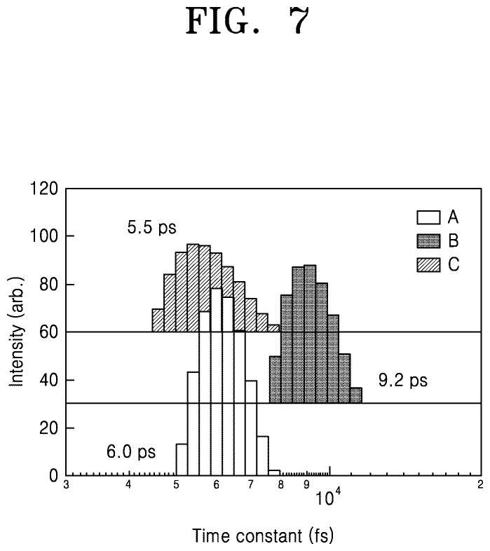

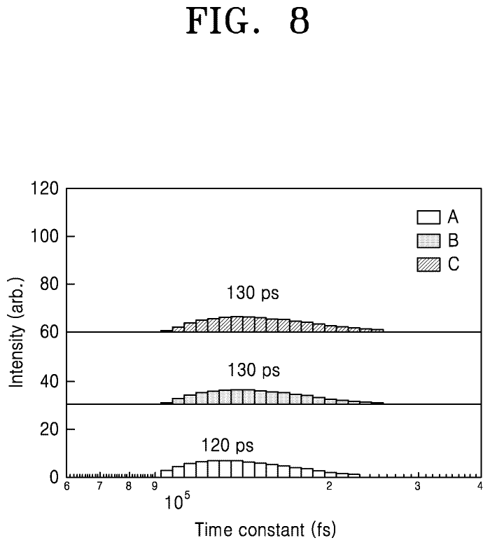

FIG. 7 is a graph showing time constants of samples of first defects divided through inverse Laplace transform in a process monitoring method according to an embodiment of the present invention, and FIG. 8 is a graph showing time constants of samples of second defects divided through inverse Laplace transform in a process monitoring method according to an embodiment of the present invention.

In the process monitoring method according to an embodiment of the present invention, a relative ratio of defects in each thin film may be determined based on a time constant divided through inverse Laplace transform. A time constant of each type of defects may be defined using a peak point of the time constant divided as shown in FIGS. 7 and 8. In this case, because the time constant is inversely proportional to a defect density as shown in Equation 3, a relative ratio of defect densities may be determined as shown in Table 2.

$${τ}_{defect} ∝ \frac{1}{{N}_{defect}} \qquad [ Equation 3 ]$$

(N_{defect}: a defect density, and τ_{defect}: a recombination time constant by defects)

TABLE 2

| | A | B | C |
|---|---|---|---|
| Defects 1 Time Constant (ps) | 6 | 9.2 | 5.5 |
| Defects 1 Density | 0.917 | 0.598 | 1.000 |
| Defects 2 Time Constant (ps) | 120 | 130 | 130 |
| Defects 2 Density | 1.000 | 0.923 | 0.923 |

Referring to Equation 3 and Table 2, it is shown that a first carrier recombination time constant is inversely proportional to a first defect density based on a first type of defects, that a second carrier recombination time constant is inversely proportional to a second defect density based on a second type of defects, and that a size relationship between the first and second carrier recombination time constants is opposite to the size relationship between the first and second defect densities in the thin film.

As described above, it is verified that changes in defects of a thin film based on changes in conditions during a process may be measured in a non-contact and non-destructive manner. As such, a deposition process may be monitored in real time based on the characteristics of time-resolved measurement of transmission and reflection of a terahertz wave after optical pumping.

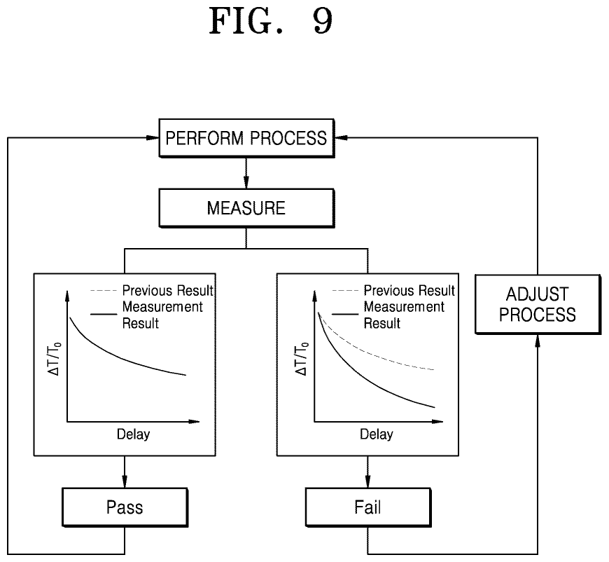

FIG. 9 is a schematic diagram showing process monitoring in a process monitoring method according to an embodiment of the present invention.

Referring to FIG. 9, characteristic information of an electromagnetic wave reacting with excited carriers in a thin film is measured during a process and, for example, a transmittance decay of the electromagnetic wave due to recombination of the optically excited carriers of the thin film is measured. Meanwhile, although FIG. 9 shows a previous result and a measurement result in the form of a transmittance decay of an electromagnetic wave over time, they may be also represented in view of a carrier recombination time constant divided by type of defects in a thin film as described above with reference to FIGS. 6 to 8.

Subsequently, when a result using the measured characteristic information of the electromagnetic wave is the same as or similar to reference data (e.g., a previous measurement result of a normal thin film), the thin film may be determined as being normal and proceed to a pass line. When the result is different from the reference data more than a certain degree, the thin film may be determined as being abnormal and proceed to a fail line.

Upon determining that the grown thin film differs from a previous state, the process may be monitored and controlled in real time through a feedback procedure for adjusting the process. For example, the process monitoring method according to an embodiment of the present invention may further include, when a defect type indicating that the thin film is abnormal is derived by comparing the reference data to carrier recombination time constant divided by type of defects in the thin film, controlling process conditions related to the derived defect type.

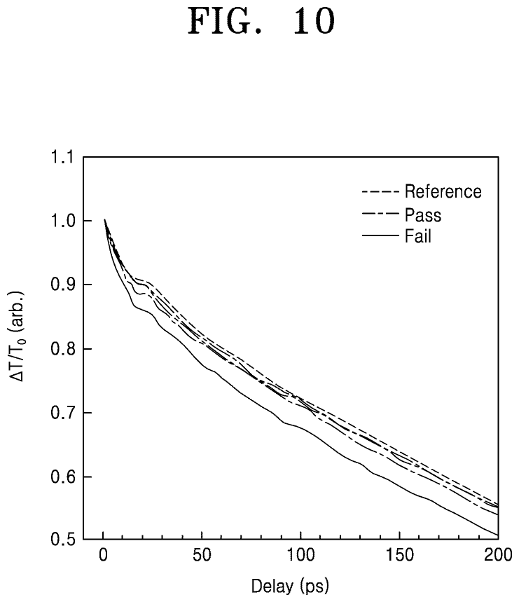

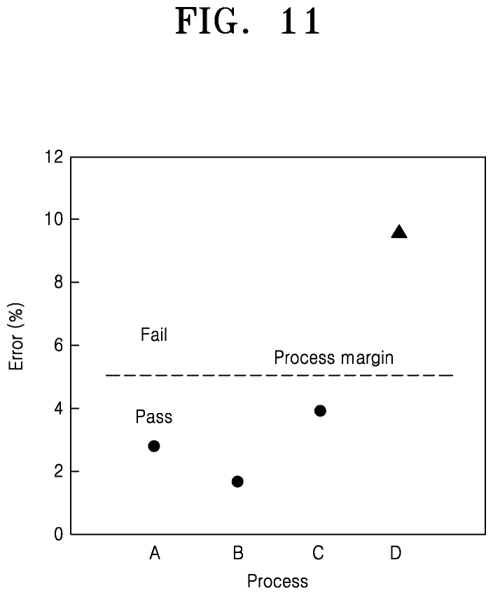

FIGS. 10 and 11 are diagrams for describing a procedure of determining a pass or fail of a process through comparison with reference data in a process monitoring method according to an embodiment of the present invention.

Referring to FIGS. 10 and 11, by comparing a measurement result measured in a current process with reference data measured under previous successful process conditions, a pass or fail of the process is determined. A certain level of process margin may be given, an error less than the process margin may be set as a pass and an error greater than the process margin may be set as a fail through comparison with the reference data, and the process may be adjusted when a fail is determined. In the current example, processes A, B, and C with errors of 5% or less may be determined as passes, and process D may be determined as a fail.

Meanwhile, in the process monitoring method according to an embodiment of the present invention, defects may be divided by type and the process may be controlled by independently determining factors which influence each type of defects.

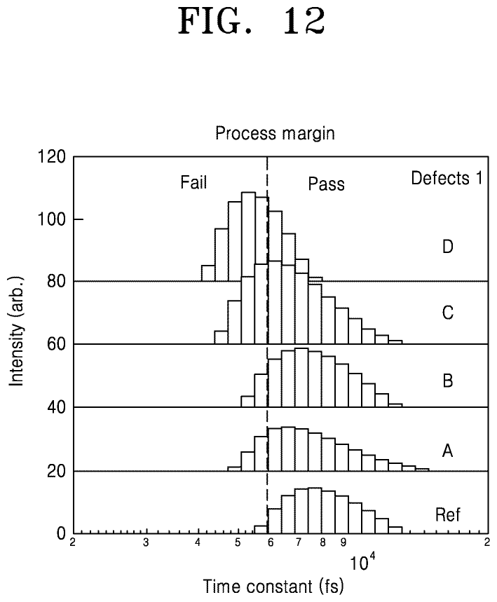

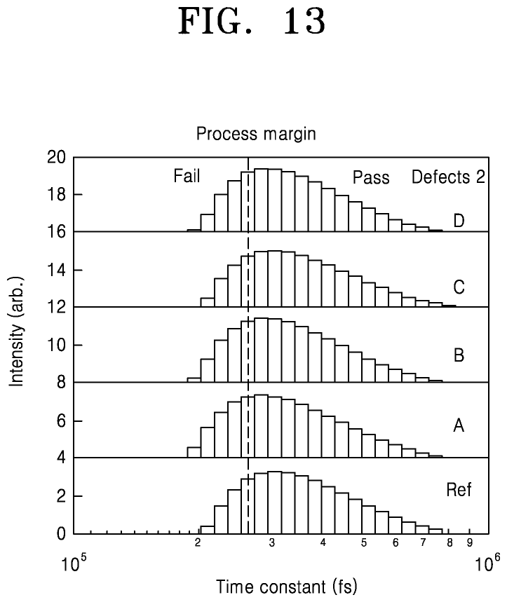

FIG. 12 is a graph showing a concept of determining a pass or fail of a process by comparing time constants using mathematical processing in view of first defects in a process monitoring method according to an embodiment of the present invention, and FIG. 13 is a graph showing a concept of determining a pass or fail of a process by comparing time constants using mathematical processing in view of second defects in a process monitoring method according to an embodiment of the present invention.

Referring to FIGS. 12 and 13, a time constant for a measurement result of reference data Ref of each type of defects is compared with a time constant of a current process by using mathematical processing (e.g., inverse Laplace transform) to determine a pass or fail based on a difference from the reference data Ref of each type of defects. Thereafter, defects of a thin film may be controlled by controlling process conditions for controlling each type of defects.

In case of defects 1 of FIG. 12, processes A, B, and C may be determined as passes, and process D may be determined as a fail. In case of defects 2 of FIG. 13, all processes have time constants similar to the reference data Ref and thus may be determined as passes. Therefore, a reason to control process conditions related to defects 1 may be provided through process monitoring.

The process monitoring method according to an embodiment of the present invention is described above on the assumption that the characteristic information of the electromagnetic wave includes a transmittance of the electromagnetic wave, and that the result using the measured characteristic information of the electromagnetic wave includes a carrier recombination time constant calculated through inverse Laplace transform on a transmittance decay function of the electromagnetic wave over time.

However, in a process monitoring method according to a modified embodiment of the present invention, the characteristic information of the electromagnetic wave may include a reflectance of the electromagnetic wave, and the result using the measured characteristic information of the electromagnetic wave may include a carrier recombination time constant calculated through inverse Laplace transform on a reflectance decay function of the electromagnetic wave over time. For example, ΔT of Equation 1 and FIGS. 4, 5, 9, and 10 may be replaced by a reflectance decay change ΔR of the electromagnetic wave, and T₀ of Equation 1 and FIGS. 4, 5, 9, and 10 may be replaced by a reflectance R₀ of the electromagnetic wave when the laser beam for forming excited carriers is not injected into the thin film. Furthermore, the first configuration stating that the carrier recombination time constant is dividable by type of defects in the thin film and is inversely proportional to a defect density in the thin film, and the second configuration stating that, when a defect type indicating that the thin film is abnormal is derived by comparing the reference data to the carrier recombination time constant divided by type of defects in the thin film, the operation controller controls process conditions related to the derived defect type, which are described above with reference to FIGS. 6 to 9, and 11 to 13, may be equally applied to a case in which the characteristic information of the electromagnetic wave is the reflectance of the electromagnetic wave as in the case in which the characteristic information of the electromagnetic wave is the transmittance of the electromagnetic wave.

While the present invention has been particularly shown and described with reference to embodiments thereof, it will be understood by one of ordinary skill in the art that various changes in form and details may be made therein without departing from the scope of the present invention as defined by the following claims.

1. A process monitoring method comprising:
injecting a laser beam capable of forming excited carriers in a thin film;
irradiating an electromagnetic wave onto the thin film while the excited carriers in the thin film are recombining;
measuring characteristic information of the electromagnetic wave reacting with the excited carriers in the thin film; and
determining whether the thin film is normal, by comparing reference data to a result using the measured characteristic information of the electromagnetic wave.

2. The process monitoring method of claim 1, wherein the characteristic information of the electromagnetic wave comprises a transmittance or reflectance of the electromagnetic wave.

3. The process monitoring method of claim 1, wherein the result using the measured characteristic information of the electromagnetic wave comprises a carrier recombination time constant calculated through inverse Laplace transform on a transmittance decay function of the electromagnetic wave over time.

4. The process monitoring method of claim 3, wherein the carrier recombination time constant is dividable by type of defects in the thin film and is inversely proportional to a defect density in the thin film.

5. The process monitoring method of claim 4, wherein the carrier recombination time constant is dividable into a first carrier recombination time constant based on a first type of defects in the thin film and a second carrier recombination time constant based on a second type of defects in the thin film.

6. The process monitoring method of claim 5, wherein the first carrier recombination time constant is inversely proportional to a first defect density based on the first type of defects, the second carrier recombination time constant is inversely proportional to a second defect density based on the second type of defects, and a size relationship between the first and second carrier recombination time constants is opposite to a size relationship between the first and second defect densities in the thin film.

7. The process monitoring method of claim 4, further comprising, when a defect type indicating that the thin film is abnormal is derived by comparing the reference data to the carrier recombination time constant divided by type of defects in the thin film, controlling process conditions related to the derived defect type.

8. The process monitoring method of claim 3, wherein the transmittance decay function of the electromagnetic wave over time is simulatable by Equation 1:
$$\frac{Δ T}{{T}_{0}} ( t ) = {\sum }_{i = 1}^{n} {a}_{i} {e}^{- t / {τ}_{i}} \qquad ( Equation 1 )$$
(ΔT: a transmittance decay change of an electromagnetic wave, T₀: a transmittance of the electromagnetic wave when a laser beam for forming excited carriers is not injected into a thin film, n: a number of defect types in the thin film, aᵢ: a carrier recombination contribution based on each type of defects in the thin film, t: time, and τᵢ: a carrier recombination time constant based on each type of defects).

9. The process monitoring method of claim 1, wherein the laser beam comprises a femtosecond laser beam.

10. The process monitoring method of claim 1, wherein the electromagnetic wave comprises a terahertz wave.

11. The process monitoring method of claim 1, wherein the excited carriers in the thin film comprise excited free electrons or holes in the thin film.

12. A process monitoring apparatus comprising:
a beam emitter for generating a laser beam to be injected into a thin film to form excited carriers in the thin film;
an electromagnetic wave irradiator for irradiating an electromagnetic wave onto the thin film while the excited carriers in the thin film are recombining;
a measurer for measuring characteristic information of the electromagnetic wave reacting with the excited carriers in the thin film; and
an operation controller for determining whether the thin film is normal, by comparing reference data to a result using the measured characteristic information of the electromagnetic wave.

13. The process monitoring apparatus of claim 12, wherein the measurer measures a transmittance or reflectance of the electromagnetic wave as the characteristic information of the electromagnetic wave.

14. The process monitoring apparatus of claim 12, wherein the operation controller calculates a carrier recombination time constant through inverse Laplace transform on a transmittance decay function of the electromagnetic wave over time, as the result using the measured characteristic information of the electromagnetic wave.

15. The process monitoring apparatus of claim 14, wherein the carrier recombination time constant is dividable by type of defects in the thin film and is inversely proportional to a defect density in the thin film.

16. The process monitoring apparatus of claim 15, wherein the carrier recombination time constant is dividable into a first carrier recombination time constant based on a first type of defects in the thin film and a second carrier recombination time constant based on a second type of defects in the thin film.

17. The process monitoring apparatus of claim 16, wherein the first carrier recombination time constant is inversely proportional to a first defect density based on the first type of defects, the second carrier recombination time constant is inversely proportional to a second defect density based on the second type of defects, and a size relationship between the first and second carrier recombination time constants is opposite to a size relationship between the first and second defect densities in the thin film.

18. The process monitoring apparatus of claim 15, wherein, when a defect type indicating that the thin film is abnormal is derived by comparing the reference data to the carrier recombination time constant divided by type of defects in the thin film, the operation controller controls process conditions related to the derived defect type.

19. The process monitoring apparatus of claim 12, wherein the beam emitter generates a femtosecond laser beam as the laser beam.

20. The process monitoring apparatus of claim 12, wherein the electromagnetic wave irradiator irradiates a terahertz wave as the electromagnetic wave.
